(19) United States
(12) Patent Application Publication
(10) Pub. No.: US 2025/0211171 A1
(43) Pub. Date: Jun. 26, 2025

(54) BROADBAND INTERSTAGE MATCHING

(71) Applicant: RENESAS ELECTRONICS AMERICA INC., MILPITAS, CA (US)

(72) Inventors: Ramanujam SRINIDHI EMBAR, San Diego, CA (US); Prathamesh Hirachandra PEDNEKAR, Bengaluru (IN); Walter Tony WOHLMUTH, Taipei (TW)

(73) Assignee: RENESAS ELECTRONICS AMERICA INC., MILPITAS, CA (US)

(21) Appl. No.: 18/390,967

(22) Filed: Dec. 20, 2023

(51) Int. Cl. H03F 1/02; H03F 1/56; H03F 3/21

(52) U.S. Cl. CPC H03F 1/0288; H03F 1/56; H03F 3/211; H03F 2200/222; H03F 2200/387; H03F 2200/451

(57) ABSTRACT

Systems and devices for impedance matching are described. A system can include a first amplification stage configured to amplify an input signal into an intermediate signal and a second amplification stage configured to amplify the intermediate signal into an output signal. The system can further include a matching network configured to match an output impedance of the first amplification stage to an input impedance of the second amplification stage. A configuration of the first amplification stage can define an impedance transformation ratio that minimizes impedance mismatch between the output impedance of the first amplification stage and the input impedance of the second amplification stage. The configuration of the first amplification stage can specify at least one attribute of one or more transistors in the first amplification stage and at least one operating condition of the first amplification stage.

### BACKGROUND

The present disclosure relates in general to systems and devices for impedance matching. Particularly, specific configurations are defined for a stage prior to an interstage matching network.

Multiple-input multiple-output (Massive MIMO) is a type of wireless communications technology that can multiply the capacity of a radio link using multiple transmission and receiving antennas to exploit multipath propagation. MIMO systems can send and receive more than one data signal simultaneously over the same radio channel by exploiting the difference in signal propagation between different antennas (e.g. due to multipath propagation). Another class of technique is massive MIMO, where base stations are equipped with a very large number of antenna elements to further improve spectral and energy efficiency. In massive MIMO technologies, the number of terminals can be much less than the number of base station antennas. Massive MIMO systems can use relatively simple beamforming strategies such as maximum ratio transmission, maximum ratio-combining, or zero forcing.

### SUMMARY

In one embodiment, a system for impedance matching is generally described. The system can include a first amplification stage configured to amplify an input signal into an intermediate signal. The system can further include a second amplification stage configured to amplify the intermediate signal into an output signal. The system can further include a matching network configured to match an output impedance of the first amplification stage to an input impedance of the second amplification stage. A configuration of the first amplification stage can define an impedance transformation ratio that minimizes impedance mismatch between the output impedance of the first amplification stage and the input impedance of the second amplification stage. The configuration of the first amplification stage can specify at least one attribute of one or more transistors in the first amplification stage and at least one operating condition of the first amplification stage.

In one embodiment, a system for impedance matching is generally described. The system can include a first amplification stage configured to amplify an input signal into an intermediate signal. The first amplification stage can include a first main amplifier and a first peaking amplifier. The system can further include a second amplification stage configured to amplify the intermediate signal into an output signal. The second amplification stage can include a second main amplifier and a second peaking amplifier. The system can further include a first matching network configured to match an output impedance of the first main amplifier to an input impedance of the second main amplifier. The system can further include a second matching network configured to match an output impedance of the first peaking amplifier to an input impedance of the second peaking amplifier. A configuration of the first amplification stage can define an impedance transformation ratio that minimizes impedance mismatch between the first amplification stage and the second amplification stage. The configuration of the first amplification stage specifies at least one attribute of one or more transistors in the first amplification stage and at least one operating condition of the first amplification stage.

In one embodiment, a system for impedance matching is generally described. The system can include an antenna. The system can further include a first amplification stage configured to amplify an input signal into an intermediate signal. The system can further include a second amplification stage configured to amplify the intermediate signal into an output signal and provide the output signal to the antenna. The system can further include a matching network configured to match an output impedance of the first amplification stage to an input impedance of the second amplification stage. A configuration of the first amplification stage can define an impedance transformation ratio that minimizes impedance mismatch between the output impedance of the first amplification stage and the input impedance of the second amplification stage. The configuration of the first amplification stage can specify at least one attribute of one or more transistors in the first amplification stage and at least one operating condition of the first amplification stage.

Further features as well as the structure and operation of various embodiments are described in detail below with reference to the accompanying drawings. In the drawings, like reference numbers indicate identical or functionally similar elements.

### BRIEF DESCRIPTION OF THE DRAWINGS

FIG. 1 is a diagram showing an example system that can implement broadband interstage matching in one embodiment.

FIG. 2 is a diagram showing another example system that can implement broadband interstage matching in one embodiment.

FIG. 3 is a diagram showing another example system that can implement broadband interstage matching in one embodiment.

FIG. 4 is a diagram showing additional details of an implementation of broadband interstage matching in one embodiment.

FIG. 5 is a diagram showing an example implementation of broadband interstage matching in one embodiment.

FIG. 6 is a diagram showing another example implementation of broadband interstage matching in one embodiment.

FIG. 7 is a diagram showing another example implementation of broadband interstage matching in one embodiment.

FIG. 8 is a diagram showing another example implementation of broadband interstage matching in one embodiment.

FIG. 9 is a diagram showing another example implementation of broadband interstage matching in one embodiment.

FIG. 10 is a diagram showing another example implementation of broadband interstage matching in one embodiment.

FIG. 11 is a diagram showing another example implementation of broadband interstage matching in one embodiment.

FIG. 12 is a diagram showing another example implementation of broadband interstage matching in one embodiment.

FIG. 13 is a diagram showing another example implementation of broadband interstage matching in one embodiment.

FIG. 14 is a diagram showing another example implementation of broadband interstage matching in one embodiment.

FIG. 15 is a diagram showing another example implementation of broadband interstage matching in one embodiment.

FIG. 16 is a diagram showing another example implementation of broadband interstage matching in one embodiment.

### DETAILED DESCRIPTION

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

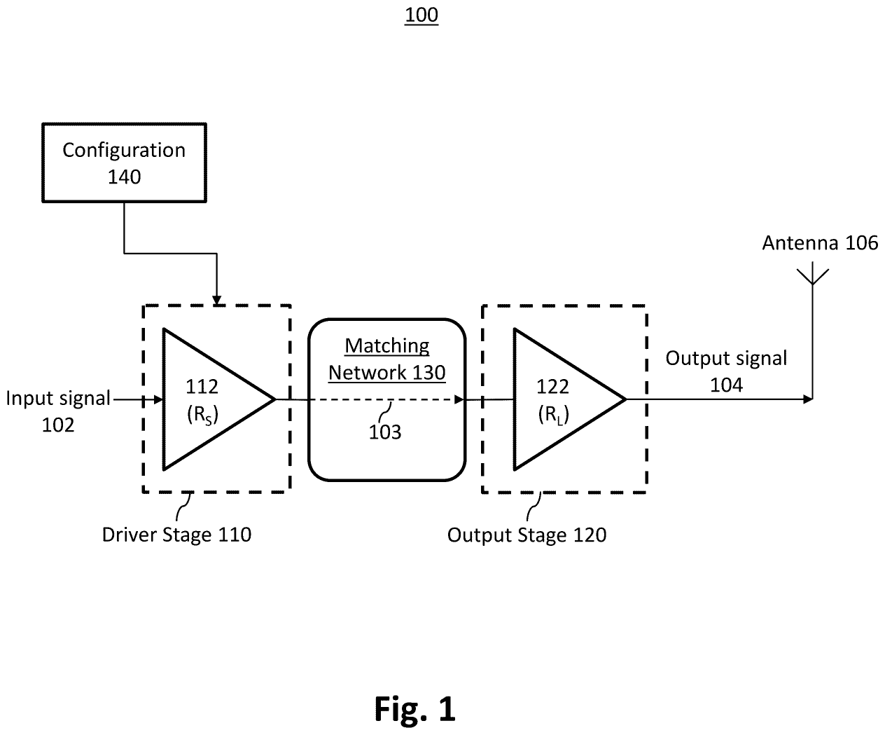

FIG. 1 is a diagram showing an example system that can implement broadband interstage matching in one embodiment. System 100 can be a part of a transmit chain implemented by one or more semiconductor devices in a radio frequency (RF) transmitter. System 100 can include at least a first amplification stage 110 (herein “driver stage 110”), a second amplification stage (herein “output stage 120”) and a matching network 130. Driver stage 110 can include at least one amplifier 112 and output stage 120 can include at least one amplifier 122. Matching network 130 can be an interstage matching network configured to create matched impedance between driver stage 110 and output stage 120. Matching network 130 can include matching elements that can be reactive circuit components, such as capacitors and inductors. System 100 can be implemented using one or more semiconductor devices.

An input signal 102 can be provided to driver stage 110. Amplifier 112 in driver stage 110 can amplify input signal 102 into an intermediate signal 103 that can be passed to output stage 120 via matching network 130. Amplifier 122 in output stage 120 can further amplify the intermediate signal 103 to generate an output signal 104. In one embodiment, if output stage 120 is an amplification stage that precedes a load, such as an antenna 106, then output signal 104 can be provided to the load. In one embodiment, input signal 102, intermediate signal 103 and output signal 104 can be radio frequency (RF) signals and antenna 106 can emit radio waves to communicate output signal 104 to other devices.

In an aspect, driver stage 110 can be a source with source resistance R_{S} and output stage 120 can be a load with load resistance R_{L}. Matching network 130 can change load resistance R_{L} to match source resistance R_{S}. If R_{S}>R_{L}, then a power match factor of m=R_{S}/R_{L}>1 can be used for boosting or increasing R_{L} to match R_{S}. If R_{S}<R_{L}, then a power match factor of m=R_{S}/R_{L}<1 can be used for decreasing R_{L} to match R_{S}. As the power match factor approaches the value of one (e.g., difference between R_{L} and R_{S} decreases), the quality factor (“Q factor”) can decrease because the Q factor can be expressed as

$$Q = \sqrt{\frac{{R}_{L}}{{R}_{S}} - 1} .$$

As the Q factor decreases, the bandwidth of system 100 can be increased and the insertion loss of system 100 can be decreased.

In massive MIMO systems, the final stages of the transmit chain prior to the antenna can pose challenges in terms of gain, efficiency and bandwidth. In an aspect, the MIMO density can determine the power capability of the final stage. Typical average power levels for each stage can range from 5 watts (W) to 10 W, each being driven by a signal with a peak to average ratio of 8.5 decibels (dB) to 9 dB. It is desirable to construct a MIMO system that can simultaneously encompass high power, high efficiency and large bandwidths while keeping the system cost low.

In an aspect, some massive MIMO systems use cascading multiple gain blocks in a transmitter chain to achieve high lineup gain, and uses conventional interstage network matching that involves matching higher impedance of input device to a lower impedance of output device. However, due to the large transformation ratio between the stages, interstage losses can be higher, which can lead to lower efficiency between subsequent stages impacting the whole transmitter lineup. Also, bandwidth can be narrower, and the number of matching elements can be higher. The increase number of matching elements can lead to an increase in footprint (e.g., on-chip area), overall cost, conduction losses, and component sensitivity which affects product yield.

To be described in more detail below, system 100 can enhance higher transmitter chain lineup efficiency, bandwidth, compact smaller footprint and overall yield by implementing driver stage 110 using a specific configuration 140. In one embodiment, configuration 140 can specify one or more specific operating conditions and settings of driver stage 110. By way of example, configuration 140 can specify one or more attributes of one or more devices or transistors in driver stage 110, and can specify one or more operating conditions of driver stage 110. The one or more attributes can include, but not limited to, a type, a size, a technology, material and/or substrate of one or more devices (e.g., transistors) being used for implementing driver stage 110, or other attributes. Configuration 140 can also specify the type of devices such as cascode devices, common source devices, Darlington configurations, of or other types of devices that can implement amplification in the amplification stages described herein. The operating conditions can include, but not limited to, a drain supply voltage (VDD) being applied to driver stage 110 or other operating conditions. In one embodiment, the operating condition being set in configuration 140 can be dependent on the one or more attributes. In one embodiment, a topology of matching network 130 can also be selected based on configuration 140. The combination of configuration 140 and selected topology of matching network 130 can optimize and enhance the performance of the transmitter chain using system 100. Further, configuration 140 can of driver stage 110 can cause the power match factor (e.g., a ratio dependent on R_{S}/R_{L}) to be closer to the value of one, thus lowering Q factor, causing the impedance transformation ratio to be closer to 1, and improving bandwidth. The impedance transformation ratio based on configuration 140 can minimize impedance mismatch between driver stage 110 and output stage 120. Also, configuration 140 of driver stage 110 can allow matching network 130 to be implemented using relatively simple components and maintain a size of matching network 130 to a relatively compact size.

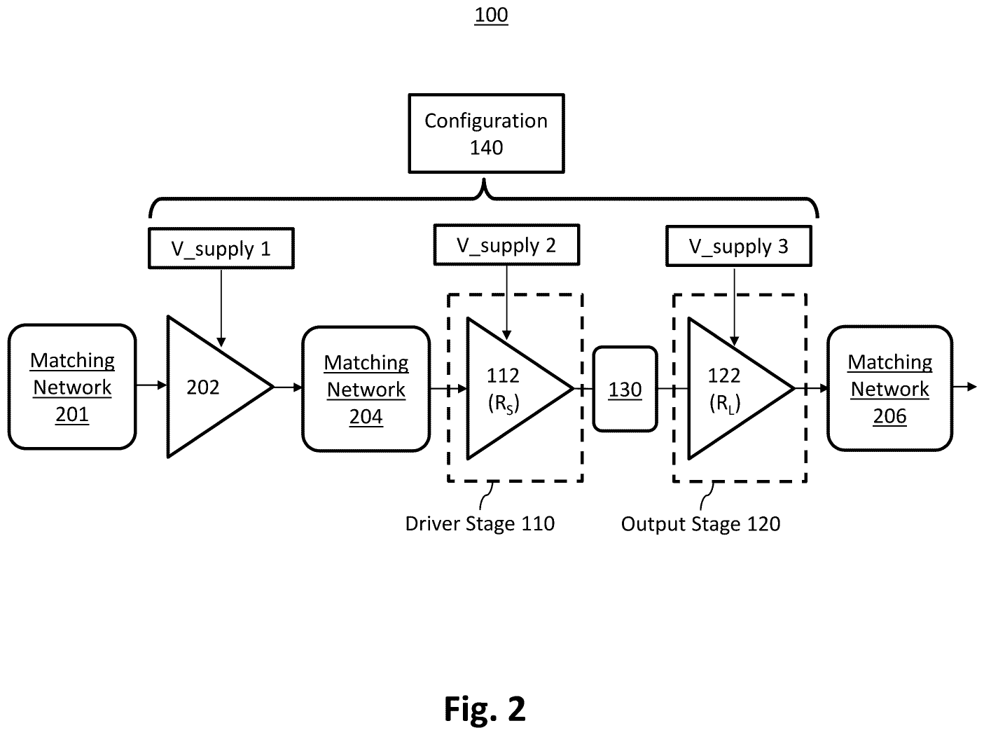

FIG. 2 is a diagram showing another example system that can implement broadband interstage matching in one embodiment. Descriptions of FIG. 2 can reference components shown in FIG. 1. In the embodiment shown in FIG. 2, the transmit chain including system 100 in FIG. 1 can include additional driver or amplification stages prior to driver stage 110 (e.g., input signal 102 can be provided by another driver or amplification stage in the transmit chain). Additional matching networks can be situated between the different driver stages to perform impedance matching. In the embedment shown in FIG. 2, another driver stage 202 can precede driver stage 110, a matching network 201 can precede driver stage 202, and a matching network 204 can be situated between driver stages 202, 110 to perform impedance matching. Further, in the embedment shown in FIG. 2, another output stage or a load such as antenna 106 can be subsequent to output stage 120 (and preceded antenna 106 in FIG. 1) and a matching network 206 can be situated between output stage 120 and the next output stage or the load to perform impedance matching. Drive stage 202, driver stage 110 and output stage 120 can be optimized based on various configurations, such as configuration 140. In the embodiment shown in FIG. 2, configuration 140 can specify different attributes and/or operating conditions for the different stages, such as specifying supply voltages V_supply1, V_supply2 and V_supply3 for driver stage 202, driver stage 110 and output stage 120, respectively.

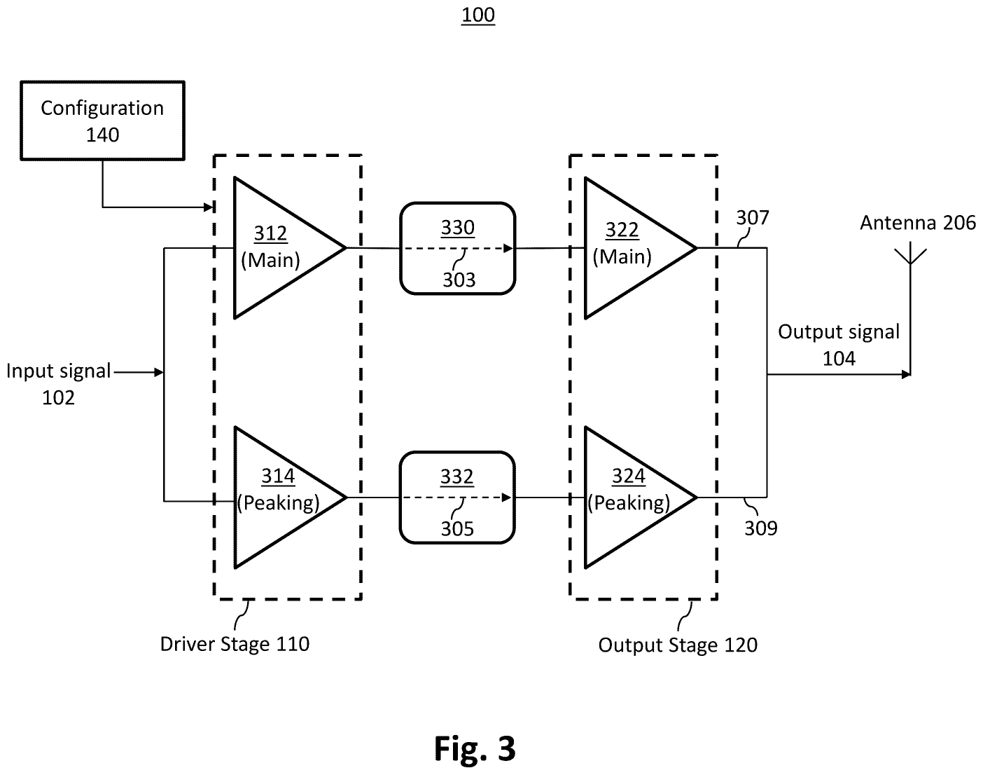

FIG. 3 is a diagram showing another example system that can implement broadband interstage matching in one embodiment. Descriptions of FIG. 3 can reference components shown in FIG. 1 and FIG. 2. In the embodiment shown in FIG. 3, driver stage 110 and output stage 120 of system 100 can be implemented by Doherty amplifiers including a main path and a peaking path. Driver stage 110 can include at least an amplifier 312 and an amplifier 314, where amplifier 312 can be a main amplifier in the main path and amplifier 314 can be a peaking amplifier in the peaking path. Matching network 330 can be an interstage matching network configured to create matched impedance between amplifier 312 in driver stage 310 and amplifier 322 in output stage 320. Output stage 120 can include at least an amplifier 322 and an amplifier 324, where amplifier 322 can be a main amplifier in the main path and amplifier 324 can be a peaking amplifier in the peaking path. Matching network 332 can be an interstage matching network configured to create matched impedance between amplifier 314 in driver stage 310 and amplifier 324 in output stage 320. Matching networks 330, 332 can include reactive circuit components, such as capacitors and inductors. Descriptions pertaining matching network 130 herein can be applicable to matching networks 330, 332 as well.

Input signal 102 can be split (e.g., by quadrature coupler) and distributed to amplifiers 312, 314 of driver stage 310. Amplifier 312 can amplify input signal 102 into an intermediate signal 303 that can be passed to amplifier 322 in output stage 320 via matching network 330. Amplifier 322 in output stage 320 can further amplify the intermediate signal 303 to generate an output signal 307. Amplifier 314 can amplify input signal 102 into an intermediate signal 305 that can be passed to amplifier 324 in output stage 320 via matching network 332. Amplifier 324 in output stage 320 can further amplify the intermediate signal 305 to generate an output signal 309. In the Doherty amplifier architecture, the amplifier 322 in the main path and amplifier 324 in the peaking path can be biased differently. Therefore, the signals 307, 309 can be out of phase by 90-degrees. Signals 307, 309 can be combined and brought into phase using, for example, quarter-wave transmission lines. The combination of signals 307, 309 can be outputted as output signal 304. Output signal 304 can be provided to a load, such as an antenna 306. In one embodiment, input signal 302, intermediate signals 303, 307, and output signals 304, 307, 309 can be radio frequency (RF) signals and antenna 306 can emit radio waves to communicate output signal 304 to other devices.

In one embodiment, configuration 140 can specify one or more of a size, technology and/or substrate of devices (e.g., transistors) being used for implementing amplifiers 312, 314 in driver stage 110 and drain supply voltages being applied to amplifiers 312, 314 in driver stage 110. Configuration 140 can specify the same or different size, technology, substrate and/or drain supply voltages for amplifiers 312, 314.

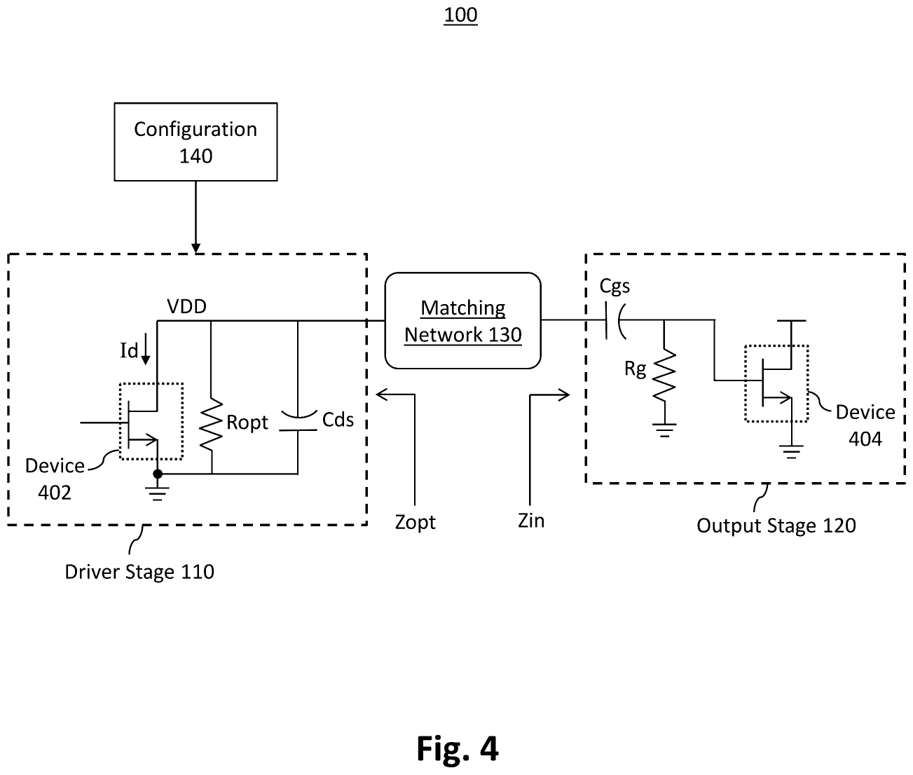

FIG. 4 is a diagram showing additional details of an implementation of broadband interstage matching in one embodiment. Descriptions of FIG. 4 can reference components shown in FIG. 1 to FIG. 3. In an embodiment shown in FIG. 4, driver stage 110 can include one or more devices, such as a device 402, that can implement amplifier 112 in FIG. 1, amplifier 312 in FIG. 2 and/or amplifier 314 in FIG. 2. Output stage 120 can include one or more devices, such as a device 404, that can implement amplifier 122 in FIG. 1, amplifier 322 in FIG. 2 and/or amplifier 324 in FIG. 2. In the example shown in FIG. 4, in order for an input impedance Zin of output stage 120) to match the output impedance of driver stage 110, configuration 140 can specify various settings and parameters in driver stage 110 to cause the output impedance of driver stage 110 to be equivalent to an optimum impedance Zopt, where Zopt is approximately identical to Zin.

In one embodiment, to achieve Zopt at the output of driver stage 110, configuration 140 can specify settings and parameters that cause the resistance across device 402 to be equivalent to optimum resistance Ropt, where Ropt is a resistance corresponding to Zopt (e.g., Ropt is the real part of Zopt). The optimum resistance Ropt can be expressed as:

$$Ropt = \frac{( VDD - Vknee )}{( I max / 2 )}$$

where VDD is the drain supply voltage to operate device 402, Vknee is the knee voltage of device 402, and Imax is the maximum value of a drain current Id flowing into the drain of device 402. In one embodiment, to achieve Ropt, configuration 140 can specify a value of VDD that causes the resistance across device 402 to be Ropt.

In one embodiment, the value of VDD being specified by configuration 140 can be dependent on the size and/or technology, or material, being used for implementing device 402. The size and/or technology of device 402 can define a range of values for VDD. In one embodiment, the technology of device 402 in driver stage 110 can have a lower breakdown voltage than the technology of device 404 in output stage 120. In another embodiment, the technology of device 402 in driver stage 110 and device 404 can be the same, but device 402 can have a smaller size, thus can have a lower breakdown voltage than device 404. The lower breakdown voltage in driver stage 110 can reduce the on resistance (RDSon) of device 402 and can also reduce loss. Based on the lower breakdown voltage in driver stage 110, configuration 140 can specify an operating condition, such as VDD, for driver stage 110 that is lower than the VDD of output stage 120.

In an aspect, the voltage standing wave ratio (VSWR) of system 100 can be a measure of how efficiently are signals being transmitted from driver stage 110 to output stage 120. VSWR can vary with impedance transformation ration Zopt/Zin. In an ideal scenario, the VSWR is equivalent to 1, which indicates that 100% of the energy is transmitted. The VSWR of system 100 shown in FIG. 4 can be expressed as:

$$VSWR ( Zopt , Zin ) = \frac{1 - \vert {Γ}_{match} \vert}{1 + \vert {Γ}_{match} \vert}$$

where Γ_{match} is a reflection coefficient and is expressed as:

$${Γ}_{match} = \frac{{Z}_{opt} - {Z}_{in}}{{Z}_{opt} + {Z}_{in} *}$$

According to the relationship between Γ_{match}, Zopt and Zin in the expression above, as the difference between Zopt and Zin decreases, the value of Γ_{match} can approach the value of 1. Therefore, configuration 140 can specify attributes of device 402 and operating conditions of driver stage 110 to cause Γ_{match} to converge to 1.

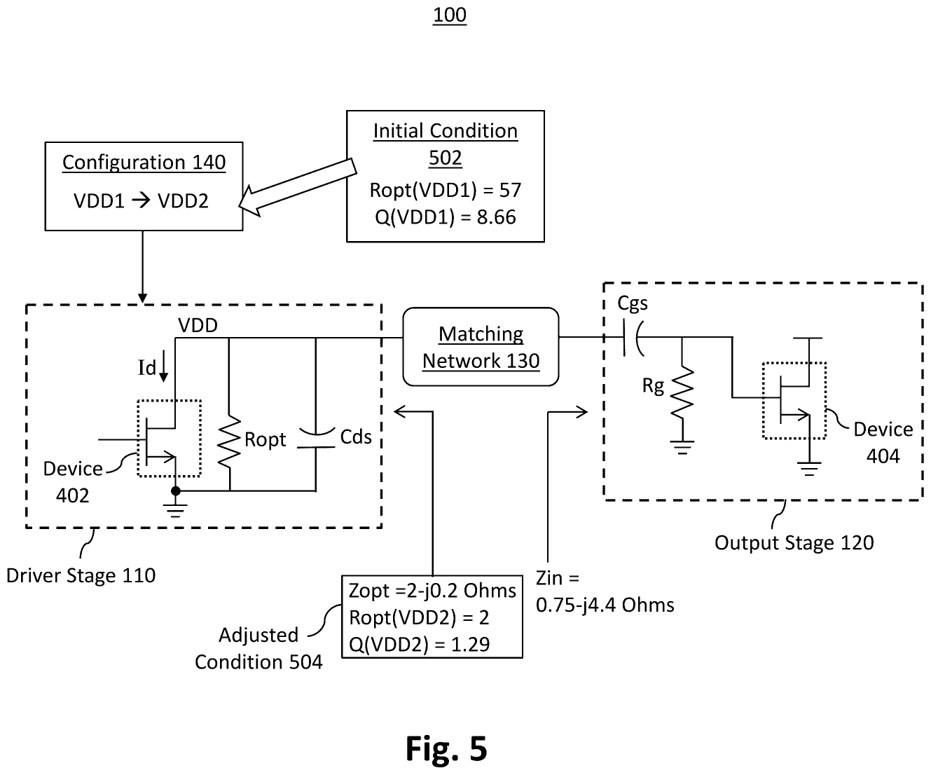

FIG. 5 is a diagram showing an example implementation of broadband interstage matching in one embodiment. Descriptions of FIG. 5 can reference components shown in FIG. 1 to FIG. 4. In an example shown in FIG. 5, an initial operating condition 502 (or initial condition 502) of driver stage 110 can include a VDD value of VDD1. If driver stage 110 operates based on VDD1, and Rg in output stage 120 is 0.75 ohms, then Ropt can be approximately 57 ohms and the Q factor can be 8.66. By way of example, configuration 140 can specify a new value of VDD, such as VDD2. If driver stage 110 operates based on VDD2, Rg in output stage 120 remains 0.75 ohms and matching network 130 remains unchanged, then Ropt can be approximately 2 ohms. The optimum impedance Zopt can become (2−j0.2) ohms and the Q factor can be lowered to approximately 1.29. Therefore, configuration 140 can specify new operating condition, such as new value of VDD in driver stage 110, to lower the Q factor and the improve the overall performance of system 100.

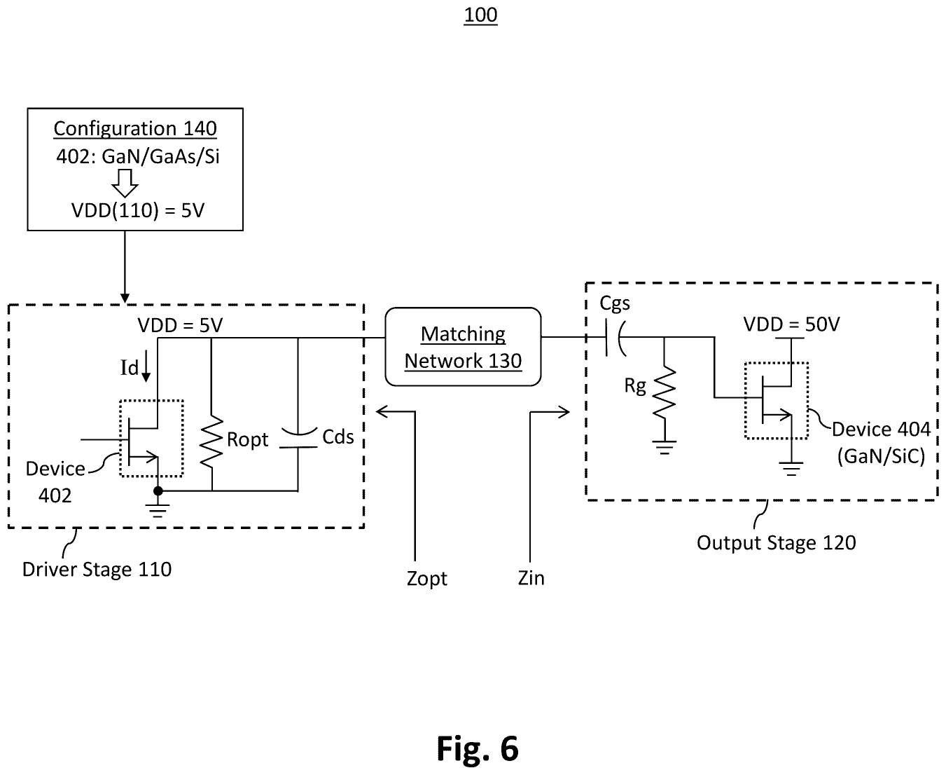

FIG. 6 is a diagram showing another example implementation of broadband interstage matching in one embodiment. Descriptions of FIG. 6 can reference components shown in FIG. 1 to FIG. 5. In an example shown in FIG. 6, device 402 can be implemented by technologies that can operate with relatively lower breakdown voltage, such as a Gallium Nitride (GaN) device, a Gallium Arsenide (GaAs) device, and a Silicon (Si) device. Device 404 can be implemented by technologies that can operate with relatively higher breakdown voltage, such as a GaN device or a Silicon Carbide (SiC) device. In response to device 402 being a GaN device, a GaAs device or a silicon device, configuration 140 can specify a value for VDD for driver stage 110 that is lower than the VDD being used for operating output stage 120. In the embodiment shown in FIG. 6, output stage 120 can operate under a VDD of 50 volts (V) and configuration 140 can specify driver stage 110 to operate under a lower VDD, such as 5V. Therefore, configuration 140 can specify operating conditions, such as a value of VDD, for driver stage 110 depending on the technology (e.g., GaN, GaAs, Si or other technologies with relatively low breakdown voltage) being used for implementing device 402 in driver stage 110. In an embodiment, the lower VDD in driver stage 110 can allow matching network 130 to use relatively simple components to match the lowered output impedance of driver stage 110, thus reducing complexity and size of matching network 130.

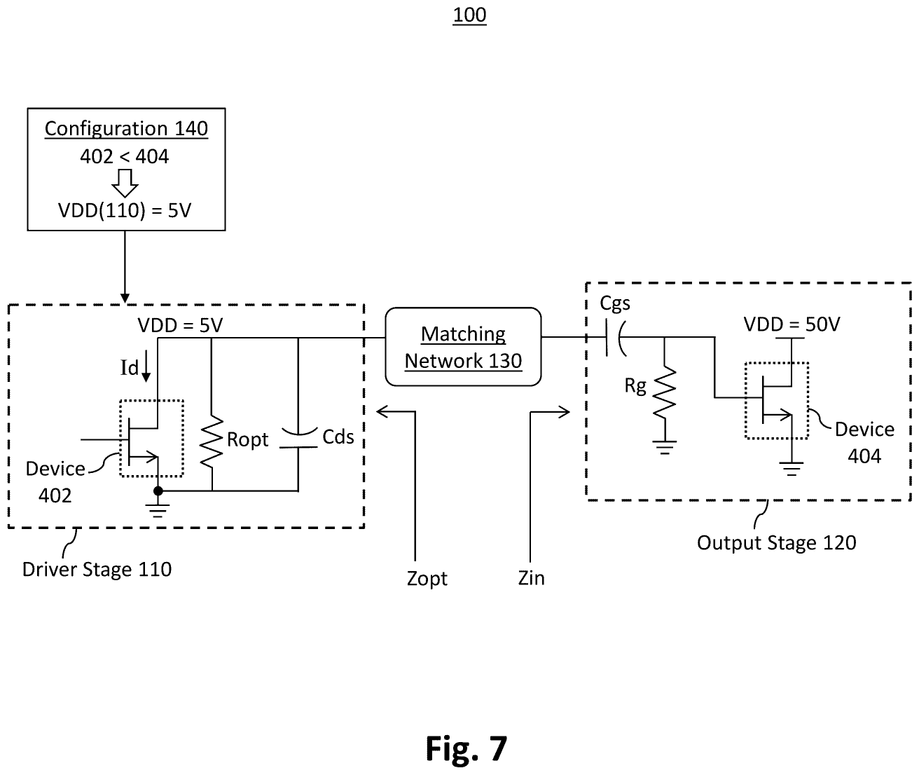

FIG. 7 is a diagram showing another example implementation of broadband interstage matching in one embodiment. Descriptions of FIG. 7 can reference components shown in FIG. 1 to FIG. 6. In an example shown in FIG. 7, device 402 can be one of a GaN device, a GaAs device and a Si device and device 404 can be one of a GaN device and a SiC device, and device 402 can be smaller than device 404. Since device 402 is smaller than device 404, device 402 can have a lower breakdown voltage than device 404 and VDD being used for operating device 402 will be lower than the VDD for operating device 404. In response to device 402 being smaller than device 404, configuration 140 can specify a value for VDD for driver stage 110 that is lower than the VDD being used for operating output stage 120. In the embodiment shown in FIG. 7, output stage 120 can operate under a VDD of 50 volts (V) and configuration 140 can specify driver stage 110 to operate under a lower VDD, such as 5V. Therefore, configuration 140 can specify operating conditions, such as a value of VDD, for driver stage 110 depending on a size of device 402 in driver stage 110. In an embodiment, the lower VDD in driver stage 110 can allow matching network 130 to use relatively simple components to match the lowered output impedance of driver stage 110, thus reducing complexity and size of matching network 130.

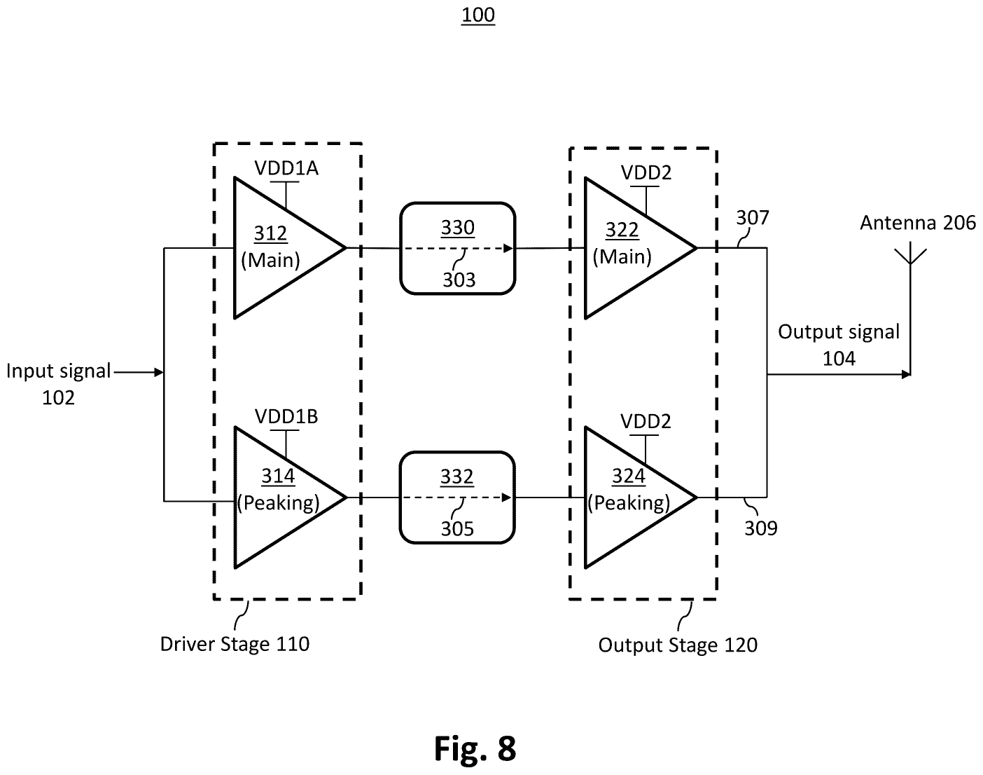

FIG. 8 is a diagram showing another example implementation of broadband interstage matching in one embodiment. Descriptions of FIG. 8 can reference components shown in FIG. 1 to FIG. 7. In an example shown in FIG. 8, driver stage 110 and output stage 120 can be implementing Doherty amplifiers (similar to FIG. 3). In one embodiment, in response to amplifier 312 being implemented by a GaN device, a GaAs device or a silicon device, configuration 140 can specify a value for VDD, such as VDD1A, for amplifier 312. VDD1A can be lower than the VDD (e.g., VDD2) being used for operating amplifiers 322, 324 in output stage 120. In response to amplifier 314 being implemented by a GaN device or a silicon device, configuration 140 can specify a value for VDD, such as VDD1B, for amplifier 314. VDD1B can be lower than the VDD (e.g., VDD2) being used for operating amplifiers 322, 324 in output stage 120. In one embodiment, VDD1A can be equivalent to VDD1B. In another embodiment, VDD1A can be different from VDD1B.

In one embodiment, in response to amplifier 312 being implemented by a device that is smaller than a device implementing amplifier 322, configuration 140 can specify a value for VDD, such as VDD1A, for amplifier 312 that is lower than VDD2 being used for operating amplifier 322. In response to amplifier 314 being implemented by a device that is smaller than a device implementing amplifier 324, configuration 140 can specify a value for VDD, such as VDD1B, for amplifier 314 that is lower than VDD2 being used for operating amplifier 324. In one embodiment, VDD1A can be equivalent to VDD1B. In another embodiment, VDD1A can be different from VDD1B. Configuration 140 can specify different operating conditions for different amplifiers or drivers in a Doherty amplifier in order to perform optimal impedance matching without increasing the complexity of matching networks 330, 332.

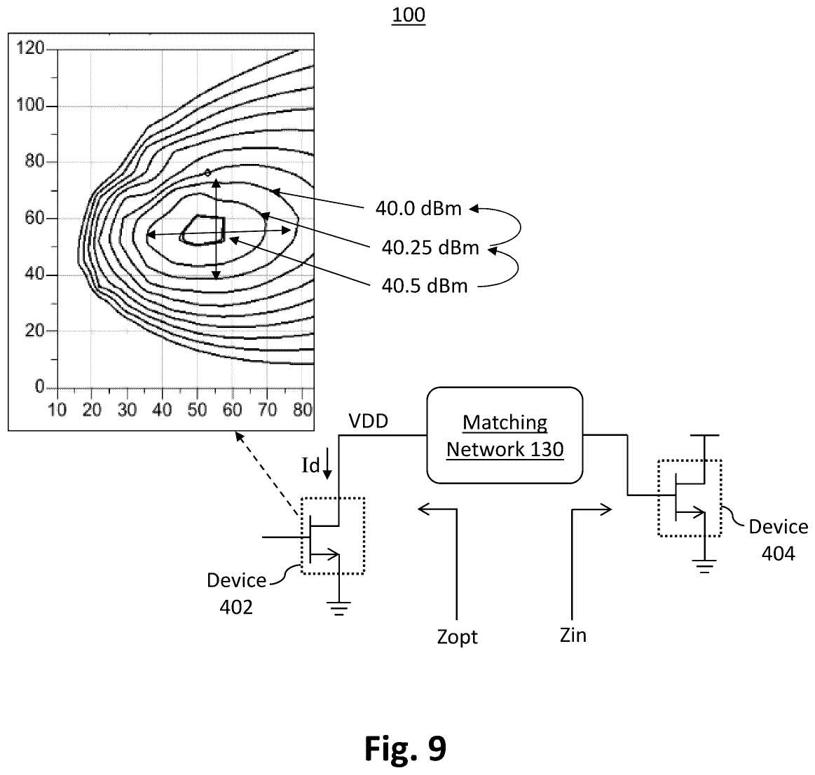

FIG. 9 is a diagram showing another example implementation of broadband interstage matching in one embodiment. Descriptions of FIG. 9 can reference components shown in FIG. 1 to FIG. 8. In an example shown in FIG. 9, configuration 140 can specify an operating condition, such as an output power from device 402 in driver stage 110, to control Zopt and to control the VSWR of system 100 to be closer to 1. In the embodiment shown in FIG. 9, a reduction of output power from device 402 can increase a range of impedance values for Zopt that can used for matching the output impedance of driver stage 110. By way of example, as the output power reduces from 40.5 dBm to 40.25 dBm then to 40.0 dBm, the range of Zopt that can be used for matching the output impedance of driver stage 110 can increase. The increased range of Zopt that can be used can increase the number of different matching network topologies that can be used for implementing matching network 130.

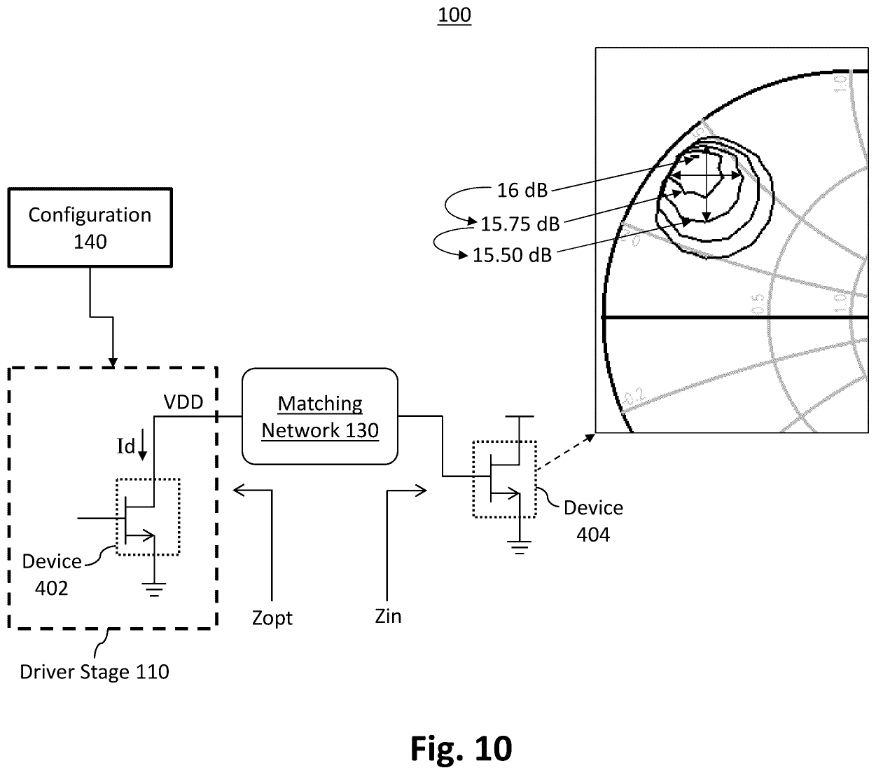

FIG. 10 is a diagram showing another example implementation of broadband interstage matching in one embodiment. Descriptions of FIG. 10 can reference components shown in FIG. 1 to FIG. 9. In an example shown in FIG. 10, in addition to configuration 140 specifying various attributes and operating conditions for driver stage 110, operating conditions of device 404 in output stage 120 can also be configured to control Zin and to control the VSWR of system 100 to be closer to 1. In the embodiment shown in FIG. 10, a reduction of gain from device 404 can increase a range of impedance values for Zin that can used for matching the input impedance of output stage 120. By way of example, as the gain reduces from 16 dB to 15.75 dB then to 15.50 dB, the range of Zin that can be used for matching the input impedance of output stage 120 can increase. The increased range of Zin that can be used can increase the number of different matching network topologies that can be used for implementing matching network 130.

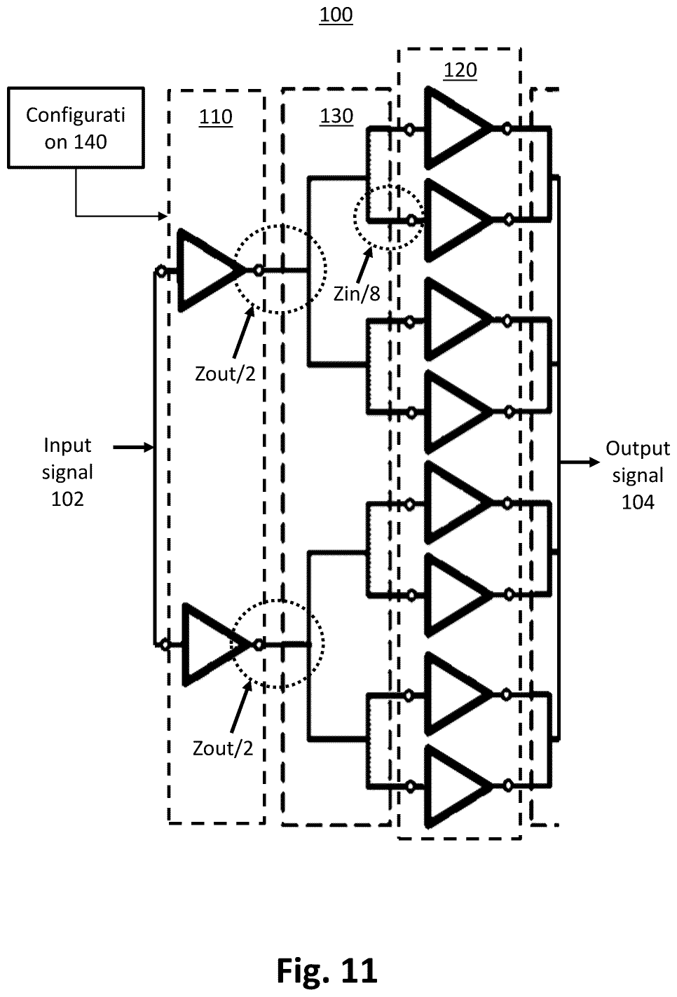

FIG. 11 is a diagram showing another example implementation of broadband interstage matching in one embodiment. Descriptions of FIG. 11 can reference components shown in FIG. 1 to FIG. 10. In an embodiment shown in FIG. 11, a device manifold in driver stage 110 and/or output stage 120 can be adjusted depending on configuration 140. In the embodiment shown in FIG. 11, each one of driver stage 110 and output stage 120 can include more than amplifiers, and output stage 120 can include more amplifiers than driver stage 110. By way of example, if configuration 140 specifies a lowered VDD, smaller device size and/or technology that uses lower VDD, then the number of amplifiers in driver stage 110 can be reduced to a number that can be less than the number of amplifiers in output stage 120. A reduction of the number of devices in driver stage 110 can reduce the number of components in matching network 130 being used for matching the output impedance of driver stage 110.

By manipulating device manifold in driver stage 110 and/or output stage 120 based on configuration 140, the impedance transformation ratio Zopt/Zin can be closer to 1 (e.g., reduce difference between Zopt and Zin), and the lowered impedance transformation ratio can lead to a lower Q factor. By way of example, if driver stage 110 is split into two amplifiers as shown in FIG. 11, then the output impedance of each amplifier in driver stage 110 will be reduced to half the total output impedance Zout of driver stage 110. Matching network 130 can use two sets of relatively smaller and less complex components having Zopt that matches Zout/2, instead of using larger or more complex components to match Zout. Also, implementing driver stage 110 using multiple amplifiers does not impact the VDD specified by configuration 140, the same VDD can be applied to the multiple amplifiers.

Also in the example shown in FIG. 11, output stage 120 is split into eight amplifiers, which causes matching network 130 to include two sets of 1:4 matching networks (e.g., one input to four output). The input impedance of each amplifier in output stage 120 will be reduced to ⅛ of the total input impedance Zin of output stage 120. Matching network 130 can use two sets of relatively smaller and less complex components having an impedance that matches Zin/8, instead of using larger or more complex components to match Zin.

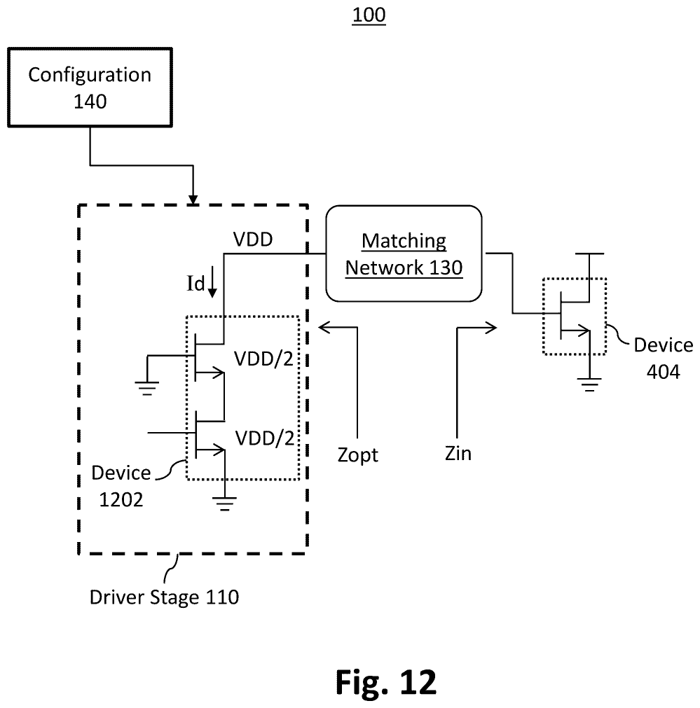

FIG. 12 is a diagram showing another example implementation of broadband interstage matching in one embodiment. Descriptions of FIG. 12 can reference components shown in FIG. 1 to FIG. 11. In an embodiment shown in FIG. 12, driver stage 110 can be implemented by a cascode device 1202. Cascode device 1202 can include two transistors or devices connected in a cascode arrangement. Example technologies or materials of cascode devices described herein can include GaN on SiC, GaN on Si, Si on insulator (SOI), or other technologies and materials for forming different types of cascode devices. Configuration 140 can specify a relatively lower VDD in response to driver stage 110 being implemented using cascode device 1202. By way of example, the VDD specified by configuration 140 can be supplied to cascode device 1202 and each device in cascode device 1202 can be operated using VDD/2. The lowered VDD for each device, such as VDD/2, can reduce the effective resistance for each device in cascode device 1202. Since one of the two devices in cascode device 1202 is connected to matching network 130, matching network 130 can use relatively less components with Zopt that can match VDD/2.

In one embodiment, configuration 140 can specify a VDD that is fixed and not adjustable. In response to configuration 140 specifying a fixed VDD, configuration 140 can further specify a device configuration that can cause Zopt to match the output impedance of driver stage 110 such that the impedance transformation ratio Zopt/Zin can be closer to 1 (e.g., reduce difference between Zopt and Zin). By way of example, if configuration 140 specifies a fixed VDD of 10V and a VDD value of 5V can cause Zopt/Zin to be approximately 1, then configuration 140 can further specify to use device configuration that can split the fixed VDD into half, such as cascode device 1202 in FIG. 12.

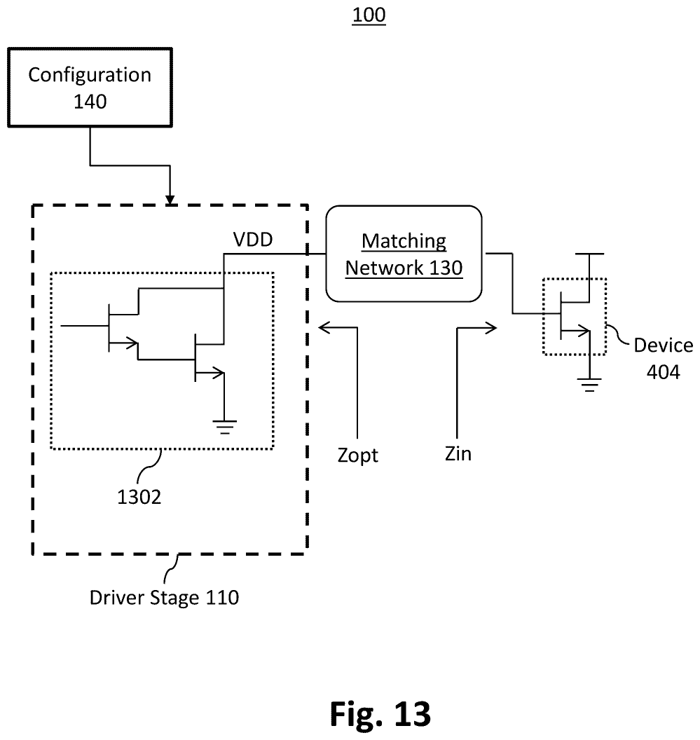

FIG. 13 is a diagram showing another example implementation of broadband interstage matching in one embodiment. Descriptions of FIG. 13 can reference components shown in FIG. 1 to FIG. 12. In an embodiment shown in FIG. 13, driver stage 110 can be implemented by a multi-transistor structure 1302 having relatively low output impedance, such as a Darlington structure. The Darlington structure, as shown by multi-transistor structure 1302, can be a circuit including two transistors or devices (e.g., bipolar transistors) with the emitter of one transistor connected to the base of the other transistor such that the current amplified by the first transistor is amplified further by the second one. Darlington structures can have relatively high input impedance and relatively low output impedance. Thus, using Darlington structure to implement multi-transistor structure 1302 can allow matching network 130 to use relatively less components with Zopt that can match the lowered output impedance of multi-transistor structure 1302.

In one embodiment, configuration 140 can specify a VDD that is fixed and not adjustable. In response to configuration 140 specifying a fixed VDD, configuration 140 can further specify a device configuration that can operate using a VDD that is lower than the fixed VDD in order to cause the impedance transformation ratio Zopt/Zin can be closer to 1 (e.g., reduce difference between Zopt and Zin). By way of example, if configuration 140 specifies a fixed VDD of 10V, then configuration 140 can further specify to use device configuration that can operate driver stage 110 using a VDD that is lower than 10V, such as multi-transistor structure 1302 in FIG. 13.

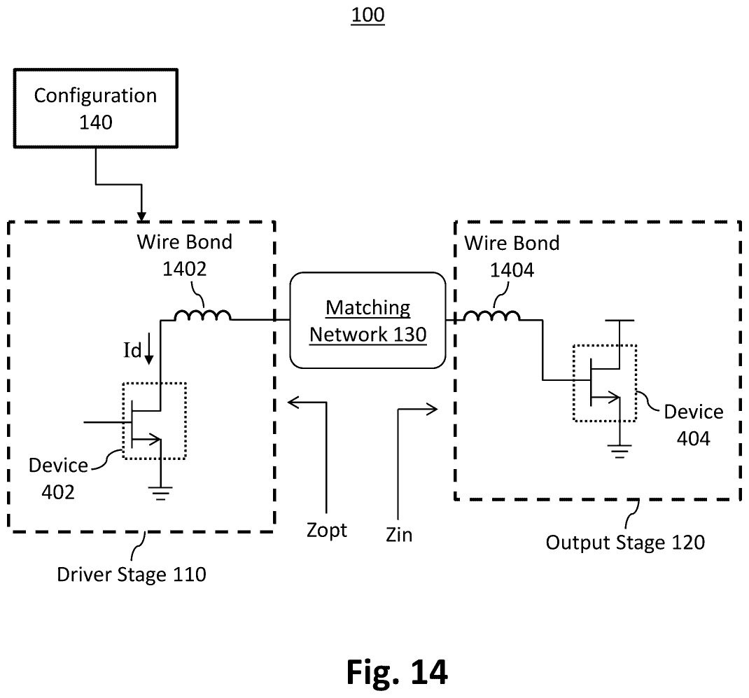

FIG. 14 is a diagram showing another example implementation of broadband interstage matching in one embodiment. Descriptions of FIG. 14 can reference components shown in FIG. 1 to FIG. 13. In an embodiment shown in FIG. 14, devices 402, 404 can be interconnected with matching network 130 using wire bonds 1402, 1404, respectively. Wire geometry of wire bonds 1402, 1404 can impact total inductance of driver stage 110 and output stage 120, hence impact Zopt and Zin as well. Configuration 140 can specify various wire geometry of wire bonds 1402, 1404, such as their thickness, diameter, number of wire, width, radius, total number of wires in parallel. The specification of wire bond geometry by configuration 140 can control Zopt and Zin such that the impedance transformation ratio Zopt/Zin can be closer to 1 (e.g., reduce difference between Zopt and Zin). The specification of wire bond geometry can allow Zopt and/or Zin to be tuned without changing matching network 130. Therefore, matching network 130 with relatively less complex components can be used and wire bond geometry can be adjusted based on the matching network being used.

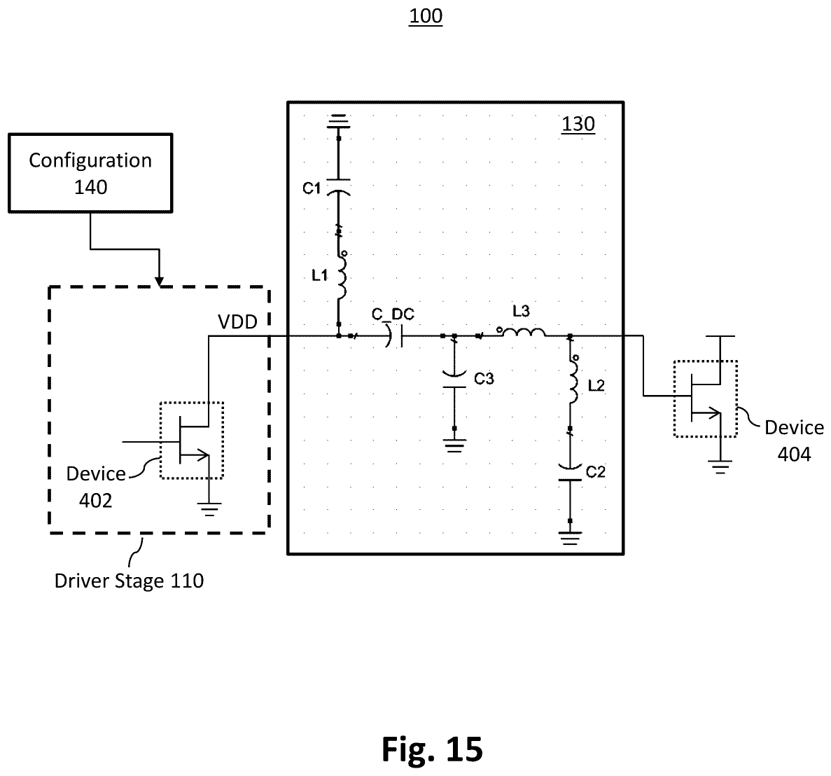

FIG. 15 is a diagram showing another example implementation of broadband interstage matching in one embodiment. Descriptions of FIG. 15 can reference components shown in FIG. 1 to FIG. 14. In an embodiment shown in FIG. 15, an example implementation of matching network 130 is shown. The matching network 130 in FIG. 15 is a single section matching network including various matching elements such as capacitors C1, C2, C3, C_DC and inductors (e.g., wires or transmission lines) L1, L2, L3. In one embodiment, the matching network 130 can be chosen based on the specifications in configuration 140. In one embodiment, matching elements C1 and L1 can be re-used as part of a first bias network on the input side of matching network 130. By using matching elements C1, L1 as part of the first bias network, the matching elements C1 and L2 can also be re-used as part of a second bias network on the output side of matching network 130 such that the second bias network does not need to constructed separately. Therefore, circuit board space can be preserved.

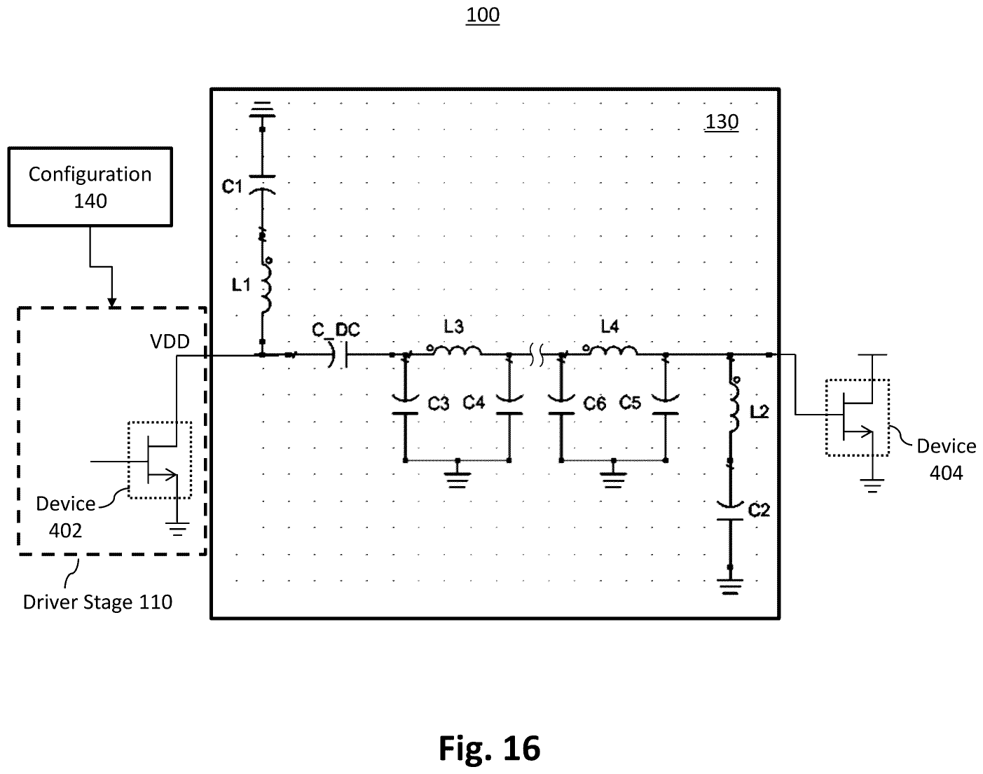

FIG. 16 is a diagram showing another example implementation of broadband interstage matching in one embodiment. Descriptions of FIG. 16 can reference components shown in FIG. 1 to FIG. 15. In an embodiment shown in FIG. 16, an example implementation of matching network 130 is shown. The matching network 130 in FIG. 16 is a multi-section matching network including various matching elements such as capacitors C1, C2, C3, C4, C5, C6, C_DC and inductors (e.g., wires or transmission lines) L1, L2, L3, L4. In one embodiment, if a bandwidth of system 100 is limited to a fixed value, then a muti-section matching network such as the embodiment shown in FIG. 16 can be used for impedance matching between driver stage 110 and output stage 120. Similar to the embodiment shown in FIG. 15, matching elements such as C1, L1 and C2, L2 can be re-used as bias networks. Note that a single section, such as the embodiment shown in FIG. 15, can result in less insertion loss when compared to the multi-section matching network in FIG. 16, but the multi-section matching network of FIG. 16 can be used for implementations where bandwidth may be limited.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements, if any, in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A system comprising:
a first amplification stage configured to amplify an input signal into an intermediate signal;
a second amplification stage configured to amplify the intermediate signal into an output signal; and
a matching network configured to match an output impedance of the first amplification stage to an input impedance of the second amplification stage, wherein:
a configuration of the first amplification stage defines an impedance transformation ratio that minimizes impedance mismatch between the output impedance of the first amplification stage and the input impedance of the second amplification stage; and
the configuration of the first amplification stage specifies at least one of:
at least one attribute of one or more transistors in the first amplification stage; and
at least one operating condition of the first amplification stage.

2. The system of claim 1, wherein:
the at least one attribute comprises at least one of:
a type of the one or more transistors in the first amplification stage;
a material of the one or more transistor in the first amplification stage; and
a size of the one or more transistors; and
the at least one operating condition comprises at least a supply voltage being used for operating the first amplification stage.

3. The system of claim 2, wherein the supply voltage is dependent on the material of the one or more transistors in the first amplification stage.

4. The system of claim 1, wherein the at least one operating condition of the first amplification stage comprises a first supply voltage being used for operating the first amplification stage, and the first supply voltage is less than a second supply voltage being used for operating the second amplification stage.

5. The system of claim 1, wherein the at least one attribute comprises a size of the one or more transistors in the first amplification stage, and the size of the one or more transistors in the first amplification stage is smaller than a size of one or more transistors in the second amplification stage.

6. The system of claim 1, wherein:
the at least one attribute comprises a material of the one or more transistors in the first amplification stage, and the material is one of Gallium Nitride (GaN) on Silicon Carbide (SiC), GaN on Silicon (Si), Gallium Arsenide (GaAs), Si on Insulator (SOI) and Silicon (Si); and
the second amplification stage comprises one or more transistors formed by one of GaN on SiC and GaN on Si.

7. The system of claim 1, wherein the first amplification stage and the second amplification stage are Doherty amplifiers.

8. The system of claim 1, wherein the one or more transistors in first amplification stage comprises at least one cascode device.

9. The system of claim 1, wherein the one or more transistors in first amplification stage comprises at least one Darlington structure.

10. The system of claim 1, wherein the configuration specifies the at least one attribute and the at least one operating condition to cause the impedance transformation ratio to be close to the value of one.

11. A system comprising:
a first amplification stage configured to amplify an input signal into an intermediate signal, wherein the first amplification stage comprises a first main amplifier and a first peaking amplifier;
a second amplification stage configured to amplify the intermediate signal into an output signal, wherein the second amplification stage comprises a second main amplifier and a second peaking amplifier;
a first matching network configured to match an output impedance of the first main amplifier to an input impedance of the second main amplifier; and
a second matching network configured to match an output impedance of the first peaking amplifier to an input impedance of the second peaking amplifier, wherein:
a configuration of the first amplification stage defines an impedance transformation ratio that minimizes impedance mismatch between the first amplification stage and the second amplification stage; and
the configuration of the first amplification stage specifies at least one of:
at least one attribute of one or more transistors in the first amplification stage; and
at least one operating condition of the first amplification stage.

12. The system of claim 11, wherein:
the at least one attribute comprises at least one of:
a type of the one or more transistors in the first amplification stage;
a material of the one or more transistors in the first amplification stage; and
a size of the one or more transistors; and
the at least one operating condition comprises at least one of a supply voltage being used for operating the first amplification stage.

13. The system of claim 12, wherein the supply voltage is dependent on the material of the one or more transistors in the first amplification stage.

14. The system of claim 11, wherein the at least one operating condition of the first amplification stage comprises a first supply voltage being used for operating the first main amplifier and the first peaking amplifier, and the first supply voltage is less than a second supply voltage being used for operating the second main amplifier and the second peaking amplifier.

15. The system of claim 11, wherein the at least one attribute comprises a size of the one or more transistors in the first amplification stage, and the size of the one or more transistors in the first amplification stage is smaller than a size of one or more transistors in the second amplification stage.

16. The system of claim 11, wherein:
the at least one attribute comprises a material of the one or more transistors in the first amplification stage, and the material is one of Gallium Nitride (GaN) on Silicon Carbide (SiC), GaN on Silicon (Si), Gallium Arsenide (GaAs), Si on insulator (SOI) and Silicon (Si); and
the second amplification stage comprises one or more transistors formed by one of GaN on SiC and GaN on Si.

17. The system of claim 11, wherein the configuration specifies the at least one attribute and the at least one operating condition to cause the impedance transformation ratio to be close to the value of one.

18. A system comprising:
an antenna;
a first amplification stage configured to amplify an input signal into an intermediate signal;
a second amplification stage configured to:
amplify the intermediate signal into an output signal; and
provide the output signal to the antenna; and
a matching network configured to match an output impedance of the first amplification stage to an input impedance of the second amplification stage, wherein:
a configuration of the first amplification stage and the second amplification stage defines an impedance transformation ratio that minimizes impedance mismatch between the output impedance of the first amplification stage and the input impedance of the second amplification stage; and
the configuration specifies at least one of:
at least one attribute of one or more transistors in the first amplification stage; and
at least one operating condition of the first amplification stage and the second amplification stage.

19. The system of claim 18, wherein:
the at least one attribute comprises at least one of:
a type of the one or more transistors in the first amplification stage;
a material of the one or more transistors in the first amplification stage; and
a size of the one or more transistors;
the at least one operating condition comprises at least one of:
a supply voltage being used for operating the first amplification stage;
an output power from the first amplification stage; and
a gain of the second amplification stage.

20. The system of claim 18, wherein the at least one operating condition of the first amplification stage comprises a first supply voltage being used for operating the first amplification stage, and the first supply voltage is less than a second supply voltage being used for operating the second amplification stage.
